(19) United States
(12) Patent Application Publication
(10) Pub. No.: US 2019/0090391 A1
(43) Pub. Date: Mar. 21, 2019

(54) INTERCONNECT SUBSTRATE HAVING STRESS MODULATOR AND FLIP CHIP ASSEMBLY THEREOF

(71) Applicant: BRIDGE SEMICONDUCTOR CORP., Taipei City (TW)

(72) Inventors: Charles W. C. LIN, Singapore (SG); Chia-Chung WANG, Hsinchu County (TW)

(21) Appl. No.: 16/194,023

(22) Filed: Nov. 16, 2018

Related U.S. Application Data
(63) Continuation-in-part of application No. 16/046,243, filed on Jul. 26, 2018.
Application No. 16/046,243 is a continuation-in-part of application No. 14/846,987, filed on Sep. 7, 2015.
Application No. 14/846,987 is a continuation-in-part of application No. 15/080,427, filed on Mar. 24, 2016, now abandoned.
Application No. 15/080,427 is a continuation-in-part of application No. 15/605,920, filed on May 25, 2017.
Application No. 15/605,920 is a continuation-in-part of application No. 15/642,253, filed on Jul. 5, 2017.
Application No. 15/642,253 is a continuation-in-part of application No. 15/785,426, filed on Oct. 16, 2017.
Application No. 15/785,426 is a continuation-in-part of application No. 15/881,119, filed on Jan. 26, 2018.
Application No. 15/881,119 is a continuation-in-part of application No. 15/908,838, filed on Mar. 1, 2018.
Application No. 15/908,838 is a continuation-in-part of application No. 15/976,307, filed on May 10, 2018.
Application No. 16/046,243 is a continuation-in-part of application No. 14/846,987, filed on Sep. 7, 2015.
Application No. 14/846,987 is a continuation-in-part of application No. 15/080,427, filed on Mar. 24, 2016, now abandoned.
Application No. 15/080,427 is a continuation-in-part of application No. 15/605,920, filed on May 25, 2017.
Application No. 15/605,920 is a continuation-in-part of application No. 15/642,253, filed on Jul. 5, 2017.
Application No. 15/642,253 is a continuation-in-part of application No. 15/881,119, filed on Jan. 26, 2018.
Application No. 15/881,119 is a continuation-in-part of application No. 15/908,838, filed on Mar. 1, 2018.
Application No. 15/908,838 is a continuation-in-part of application No. 15/976,307, filed on May 10, 2018.
Application No. 14/846,987 is a continuation-in-part of application No. 14/621,332, filed on Feb. 12, 2015, now abandoned.
Application No. 15/080,427 is a continuation-in-part of application No. 14/621,332, filed on Feb. 12, 2015, now abandoned.
Application No. 14/621,332 is a continuation-in-part of application No. 14/846,987, filed on Sep. 7, 2015.
Application No. 15/605,920 is a continuation-in-part of application No. 14/621,332, filed on Feb. 12, 2015, now abandoned.
Application No. 14/621,332 is a continuation-in-part of application No. 14/846,987, filed on Sep. 7, 2015.
Application No. 15/642,253 is a continuation-in-part of application No. 14/621,332, filed on Feb. 12, 2015, now abandoned.
Application No. 14/621,332 is a continuation-in-part of application No. 14/846,987, filed on Sep. 7, 2015.
Application No. 15/785,426 is a continuation-in-part of application No. 15/642,253, filed on Jul. 5, 2017.
Application No. 15/642,253 is a continuation-in-part of application No. 15/642,256, filed on Jul. 5, 2017, now abandoned.
Application No. 15/881,119 is a continuation-in-part of application No. 15/605,920, filed on May 25, 2017.
Application No. 15/605,920 is a continuation-in-part of application No. 14/621,332, filed on Feb. 12, 2015, now abandoned.
Application No. 14/621,332 is a continuation-in-part of application No. 14/846,987, filed on Sep. 7, 2015.
Application No. 15/908,838 is a continuation-in-part of application No. 15/415,844, filed on Jan. 25, 2017, now abandoned.
Application No. 15/415,844 is a continuation-in-part of application No. 15/415,846, filed on Jan. 25, 2017, now abandoned.
Application No. 15/415,846 is a continuation-in-part of application No. 15/473,629, filed on Mar. 30, 2017, now Pat. No. 10,134,711.
Application No. 15/473,629 is a continuation-in-part of application No. 15/642,253, filed on Jul. 5, 2017.
Application No. 15/415,844 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/289,126 is a continuation-in-part of application No. 15/353,537, filed on Nov. 16, 2016.
Application No. 15/415,846 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/289,126 is a continuation-in-part of application No. 15/353,537, filed on Nov. 16, 2016.
Application No. 15/473,629 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/289,126 is a continuation-in-part of application No. 15/353,537, filed on Nov. 16, 2016.
Application No. 15/353,537 is a continuation-in-part of application No. 15/415,844, filed on Jan. 25, 2017, now abandoned.
Application No. 15/415,844 is a continuation-in-part of application No. 15/415,846, filed on Jan. 25, 2017, now abandoned.
Application No. 15/415,846 is a continuation-in-part of application No. 15/462,536, filed on Mar. 17, 2017, now abandoned.
Application No. 15/289,126 is a continuation-in-part of application No. 15/166,185, filed on May 26, 2016, now Pat. No. 10,121,768.
Application No. 15/353,537 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/462,536 is a continuation-in-part of application No. 15/166,185, filed on May 26, 2016, now Pat. No. 10,121,768.
Application No. 15/166,185 is a continuation-in-part of application No. 15/289,126, filed on Oct. 8, 2016, now abandoned.
Application No. 15/289,126 is a continuation-in-part of application No. 15/353,537, filed on Nov. 16, 2016.
(60) Provisional application No. 61/949,652, filed on Mar. 7, 2014.
(60) Provisional application No. 62/166,771, filed on May 27, 2015.

(51) Int. Cl. H05K 13/00; H05K 13/04; H01L 21/56; H01L 21/48; H01L 23/498

(52) U.S. Cl. CPC H05K 13/00; H05K 13/0469; H01L 21/568; H01L 23/3121; H01L 23/49838; H01L 23/49822; H01L 21/4857

(57) ABSTRACT

An interconnect substrate mainly includes a first wiring layer, vertical connecting elements, a stress modulator, a buffering layer and a resin layer. The resin layer bonds sidewalls of the stress modulator and lateral surface of the vertical connecting elements laterally surrounding the stress modulator. The first wiring layer includes interconnect pads in the buffering layer and routing traces in the resin layer. The routing traces are integrated with the interconnect pads and electrically coupled to the vertical connecting elements. The interconnect pads are superimposed over and spaced from the stress modulator by the buffering layer, so that bumps for device connection can be mounted at the area covered by the stress modulator, thereby avoiding cracking of the bumps.

### CROSS REFERENCE TO RELATED APPLICATIONS

This application is a continuation-in-part of U.S. application Ser. No. 16/046,243 filed Jul. 26, 2018, a continuation-in-part of U.S. application Ser. No. 14/846,987 filed Sep. 7, 2015, a continuation-in-part of U.S. application Ser. No. 15/080,427 filed Mar. 24, 2016, a continuation-in-part of U.S. application Ser. No. 15/605,920 filed May 25, 2017, a continuation-in-part of U.S. application Ser. No. 15/642,253 filed Jul. 5, 2017, a continuation-in-part of U.S. application Ser. No. 15/785,426 filed Oct. 16, 2017, a continuation-in-part of U.S. application Ser. No. 15/881,119 filed Jan. 26, 2018, a continuation-in-part of U.S. application Ser. No. 15/908,838 filed Mar. 1, 2018, and a continuation-in-part of U.S. application Ser. No. 15/976,307 filed May 10, 2018.

The U.S. application Ser. No. 16/046,243 is a continuation-in-part of U.S. application Ser. No. 14/846,987 filed Sep. 7, 2015, a continuation-in-part of U.S. application Ser. No. 15/080,427 filed Mar. 24, 2016, a continuation-in-part of U.S. application Ser. No. 15/605,920 filed May 25, 2017, a continuation-in-part of U.S. application Ser. No. 15/642,253 filed Jul. 5, 2017, a continuation-in-part of U.S. application Ser. No. 15/881,119 filed Jan. 26, 2018, a continuation-in-part of U.S. application Ser. No. 15/908,838 filed Mar. 1, 2018, and a continuation-in-part of U.S. application Ser. No. 15/976,307 filed May 10, 2018. The U.S. application Ser. No. 14/846,987 is a continuation-in-part of U.S. application Ser. No. 14/621,332 filed Feb. 12, 2015. The U.S. application Ser. No. 15/080,427 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/605,920 is a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/642,253 is a continuation-in-part of U.S. application Ser. No. 14/621,332 filed Feb. 12, 2015, and a continuation-in-part of U.S. application Ser. No. 14/846,987 filed Sep. 7, 2015. The U.S. application Ser. No. 15/785,426 is a continuation-in-part of U.S. application Ser. No. 15/642,253 filed Jul. 5, 2017 and a continuation-in-part of U.S. application Ser. No. 15/642,256 filed Jul. 5, 2017. The U.S. application Ser. No. 15/881,119 is a continuation-in-part of U.S. application Ser. No. 15/605,920 filed May 25, 2017, a continuation-in-part of U.S. application Ser. No. 14/621,332 filed Feb. 12, 2015 and a continuation-in-part of U.S. application Ser. No. 14/846,987 filed Sep. 7, 2015. The U.S. application Ser. No. 15/908,838 is a continuation-in-part of U.S. application Ser. No. 15/415,844 filed Jan. 25, 2017, a continuation-in-part of U.S. application Ser. No. 15/415,846 filed Jan. 25, 2017, a continuation-in-part of U.S. application Ser. No. 15/473,629 filed Mar. 30, 2017 and a continuation-in-part of U.S. application Ser. No. 15/642,253 filed Jul. 5, 2017. The U.S. application Ser. No. 15/976,307 is a division of pending U.S. patent application Ser. No. 14/621,332 filed Feb. 12, 2015.

The U.S. application Ser. No. 14/621,332 claims benefit of U.S. Provisional Application Ser. No. 61/949,652 filed Mar. 7, 2014. The U.S. application Ser. Nos. 15/415,844 and 15/415,846 are continuation-in-part of U.S. application Ser. No. 15/166,185 filed May 26, 2016, continuation-in-part of U.S. application Ser. No. 15/289,126 filed Oct. 8, 2016 and continuation-in-part of U.S. application Ser. No. 15/353,537 filed Nov. 16, 2016. The U.S. application Ser. No. 15/473,629 is a continuation-in-part of U.S. application Ser. No. 15/166,185 filed May 26, 2016, a continuation-in-part of U.S. application Ser. No. 15/289,126 filed Oct. 8, 2016, a continuation-in-part of U.S. application Ser. No. 15/353,537 filed Nov. 16, 2016, a continuation-in-part of U.S. application Ser. No. 15/415,844 filed Jan. 25, 2017, a continuation-in-part of U.S. application Ser. No. 15/415,846 filed Jan. 25, 2017 and a continuation-in-part of U.S. application Ser. No. 15/462,536 filed Mar. 17, 2017. The U.S. application Ser. No. 15/166,185 claims the priority benefit of U.S. Provisional Application Ser. No. 62/166,771 filed May 27, 2015. The U.S. application Ser. No. 15/289,126 is a continuation-in-part of U.S. application Ser. No. 15/166,185 filed May 26, 2016. The U.S. application Ser. No. 15/353,537 is a continuation-in-part of U.S. application Ser. No. 15/166,185 filed May 26, 2016 and a continuation-in-part of U.S. application Ser. No. 15/289,126 filed Oct. 8, 2016. The U.S. application Ser. No. 15/462,536 is a continuation-in-part of U.S. application Ser. No. 15/166,185 filed May 26, 2016, a continuation-in-part ofU.S. application Ser. No. 15/289,126 filed Oct. 8, 2016 and a continuation-in-part of U.S. application Ser. No. 15/353,537 filed Nov. 16, 2016. The entirety of each of said Applications is incorporated herein by reference.

### FIELD OF THE INVENTION

The present invention relates to an interconnect substrate and a flip chip assembly using the same and, more particularly, to an interconnect substrate having a stress modulator therein and a flip chip assembly having at least one bump superimposed over the stress modulator of interconnect substrate.

### DESCRIPTION OF RELATED ART

High performance microprocessors and ASICs require advanced packaging technologies such as flip chip assembly to address various performance needs. Flip chip assembly involves providing pre-formed bumps on the chip pads, flipping the chip so that the bumps face down and are aligned with and contact matching bond sites on the package substrate, and melting the solder on the bumps to wet the bond sites. After the solder reflows it is cooled down and solidified to form solder joints between the chip and the package substrate. Compared to the face-up chip mounting configurations, flip chip provides the shortest possible leads, the lowest inductance, the highest frequencies, the best noise control, the smallest device footprints, and the lowest profile.

While flip chip technology has tremendous advantages over wire bonding, its technical limitations are significant. For instance, solder bumps are vulnerable to stresses or strains induced by thermal expansion mismatch between the semiconductor chip and the package substrate. These bumps exhibit increased electrical resistance as well as cracks and voids over time due to fatigue from thermo-mechanical stresses.

U.S. Pat. No. 9,698,072 to Brofman et al., U.S. Pat. No. 9,583,368 to Hong and U.S. Pat. No. 9,287,143 to Chen et al. disclose flip chip assemblies in which a resin or a molding compound is placed between the chip and the substrate and acts as encapsulant of the solder bumps as well as a binder between the chip and the substrate. This underfill material mechanically locks the flip chip surface to the substrate, thereby reducing the strains imposed on the small bumps. The underfill consequently prevents the bumps from being damaged (e.g., cracking, severing) during thermal expansion of the package and the long-time reliability of underlined flip chip packages is enhanced compared to counterparts without an underfill. However, drawbacks to this approach include complicated manufacturing requirements, high cost, and unpredictable bump cracks if the underfill dispensing is defective.

U.S. Pat. No. 9,773,685 to Pendse et al. and U.S. Pat. No. 9,583,367 to Huang et al. disclose flip chip assemblies in which solder bumps are connected directly onto a lead (BOL), onto a trace (BOT) or onto a narrow pad (BONP) of the substrate in hope that higher reliability can be achieved. However, as the CTE of a laminate (organic) substrate is typically in a range about 16-18 ppm/degree C. and the CTE of silicon is about 2-3 ppm/degree C., the significant CTE mismatch makes these minor modifications inefficient.

In view of the various development stages and limitations in current flip chip assemblies, there is a need to fundamentally resolve the thermal mechanical streess induced on the bumps and in the interconnect substrate due to CTE mismatches in the assembly.

### SUMMARY OF THE INVENTION

An objective of the present invention is to provide an interconnect substrate for a flip chip assembly in which flip chip bumps can be disposed above a stress modulator in the interconnect substrate so as to alleviate solder cracking defects caused by chip/substrate CTE mismatch, thereby ensuring flip chip reliability.

In accordance with the foregoing and other objectives, the present invention provides an interconnect substrate, comprising: a resin layer having a first dielectric surface and an opposite second dielectric surface; a first wiring layer disposed adjacent to the first dielectric surface and having a first conductive surface exposed from the first dielectric surface and an opposite second conductive surface at a level between the first dielectric surface and the second dielectric surface; a plurality of vertical connecting elements disposed in the resin layer and each having a first end electrically connected to the second conductive surface and an opposite second end exposed from the second dielectric surface; and a stress modulator disposed in the resin layer and having a first side facing in the second conductive surface and located at a level between the second conductive surface and the second dielectric surface, wherein (i) the stress modulator is spaced from the first wiring layer by a buffering layer, (ii) the first wiring layer includes interconnect pads and routing traces integrated with the interconnect pads, (iii) the interconnect pads are disposed in the buffering layer and superimposed over the first side of the stress modulator, (iv) the routing traces are disposed in the resin layer and electrically connects the interconnect pads and the vertical connecting elements, and (v) the buffering layer extends into gaps between the interconnect pads and the resin layer extends into gaps between the routing traces.

In another aspect, the present invention provides a semiconductor assembly, comprising: the aforementioned interconnect substrate; and a semiconductor device disposed over the interconnect substrate and electrically coupled to the interconnect pads through a plurality of bumps, wherein the bumps of the semiconductor device are aligned with and covered by the stress modulator.

In yet another aspect, the present invention provides a method of making an interconnect substrate, comprising steps of: providing a first wiring layer on a sacrificial carrier, wherein the first wiring layer has a first conductive surface detachably attached to the sacrificial carrier and includes interconnect pads and routing traces integrated with the interconnect pads; forming a plurality of vertical connecting elements on a second conductive surface of the first wiring layer opposite to the first conductive surface, wherein the vertical connecting elements each have a first end electrically coupled to the routing traces and a second end opposite to the first end; attaching a stress modulator to the first wiring layer by a buffering layer between a first side of the stress modulator and the second conductive surface of the first wiring layer, wherein the stress modulator overlaps and is spaced from the interconnect pads by the buffering layer, and the buffering layer further extends into gaps between the interconnect pads; providing a resin layer that covers sidewalls of the vertical connecting elements and sidewalls of the stress modulator and extends into gaps between the routing traces, wherein the resin layer has a first dielectric surface in contact with the sacrificial carrier and a second dielectric surface opposite to the first dielectric surface; and removing the sacrificial carrier to expose the first conductive surface of the first wiring layer and the first dielectric surface of the resin layer.

In yet another aspect, the present invention provides a method of making a semiconductor assembly, comprising steps of: providing the aforementioned interconnect substrate by the above-mentioned method; and disposing a semiconductor device over the interconnect substrate and electrically coupling the semiconductor device to the interconnect pads of the first wiring layer through a plurality of bumps, wherein the bumps of the semiconductor device are aligned with and covered by the stress modulator.

Unless specifically indicated or using the term “then” between steps, or steps necessarily occurring in a certain order, the sequence of the above-mentioned steps is not limited to that set forth above and may be changed or reordered according to desired design.

The interconnect substrate and the method of making the same according to the present invention have numerous advantages. For instance, providing the interconnect pads for bump attachment over the stress modulator is particularly advantageous as the low CTE of the stress modulator can reduce warpage in the bump attachment area and CTE mismatch between the semiconductor device and the bump attachment area can be reduced so that cracking of the bumps in connection with the interconnect pads and the semiconductor device can be avoided. Providing vertical connecting element around the stress modulator can offer vertical connecting channels between the two opposite sides of the interconnect substrate.

These and other features and advantages of the present invention will be further described and more readily apparent from the detailed description of the preferred embodiments which follows.

### BRIEF DESCRIPTION OF THE DRAWINGS

The following detailed description of the preferred embodiments of the present invention can best be understood when read in conjunction with the following drawings, in which:

FIGS. 1 and 2 are cross-sectional and top perspective views, respectively, of the structure with a first wiring layer on a sacrificial carrier in accordance with the first embodiment of the present invention;

FIGS. 3 and 4 are cross-sectional and top perspective views, respectively, of the structure of FIGS. 1 and 2 further provided with vertical connecting elements in accordance with the first embodiment of the present invention;

FIGS. 5 and 6 are cross-sectional and top perspective views, respectively, of the structure of FIGS. 3 and 4 further provided with a buffering layer in accordance with the first embodiment of the present invention;

FIGS. 7 and 8 are cross-sectional and top perspective views, respectively, of the structure of FIGS. 5 and 6 further provided with a stress modulator in accordance with the first embodiment of the present invention;

FIG. 9 is a cross-sectional view of the structure of FIG. 7 further provided with a resin layer in accordance with the first embodiment of the present invention;

FIGS. 10 and 11 are cross-sectional and top perspective views, respectively, of the structure of FIG. 9 after removal of the top portion of the resin layer in accordance with the first embodiment of the present invention;

FIGS. 12 and 13 are cross-sectional and top perspective views, respectively, of the structure of FIGS. 10 and 11 after removal of the sacrificial carrier and being inverted to finish the fabrication of an interconnect substrate in accordance with the first embodiment of the present invention;

FIGS. 14 and 15 are cross-sectional and bottom perspective views, respectively, of another aspect of the interconnect substrate in accordance with the first embodiment of the present invention;

FIG. 16 is a cross-sectional view of a semiconductor assembly having a semiconductor device electrically connected to the interconnect substrate of FIG. 12 in accordance with the first embodiment of the present invention;

FIG. 17 is a cross-sectional view of the semiconductor assembly of FIG. 16 further provided with an underfill in accordance with the first embodiment of the present invention;

FIG. 18 is a cross-sectional view of the semiconductor assembly of FIG. 17 further provided with solder balls in accordance with the first embodiment of the present invention;

FIGS. 19 and 20 are cross-sectional and bottom perspective views, respectively, of another interconnect substrate in accordance with the second embodiment of the present invention;

FIG. 21 is a cross-sectional view of a semiconductor assembly having a semiconductor device electrically connected to the interconnect substrate of FIG. 19 in accordance with the second embodiment of the present invention;

FIG. 22 is a cross-sectional view of yet another interconnect substrate in accordance with the third embodiment of the present invention;

FIG. 23 is a cross-sectional view of a semiconductor assembly having a semiconductor device electrically connected to the interconnect substrate of FIG. 22 in accordance with the third embodiment of the present invention;

FIG. 24 is a cross-sectional view of yet another interconnect substrate in accordance with the fourth embodiment of the present invention; and

FIG. 25 is a cross-sectional view of a semiconductor assembly having a semiconductor device electrically connected to the interconnect substrate of FIG. 24 in accordance with the fourth embodiment of the present invention.

### DETAILED DESCRIPTION OF THE PREFERRED EMBODIMENTS

Hereafter, examples will be provided to illustrate the embodiments of the present invention. Advantages and effects of the invention will become more apparent from the following description of the present invention. It should be noted that these accompanying figures are simplified and illustrative. The quantity, shape and size of components shown in the figures may be modified according to practical conditions, and the arrangement of components may be more complex. Other various aspects also may be practiced or applied in the invention, and various modifications and variations can be made without departing from the spirit of the invention based on various concepts and applications.

### Embodiment 1

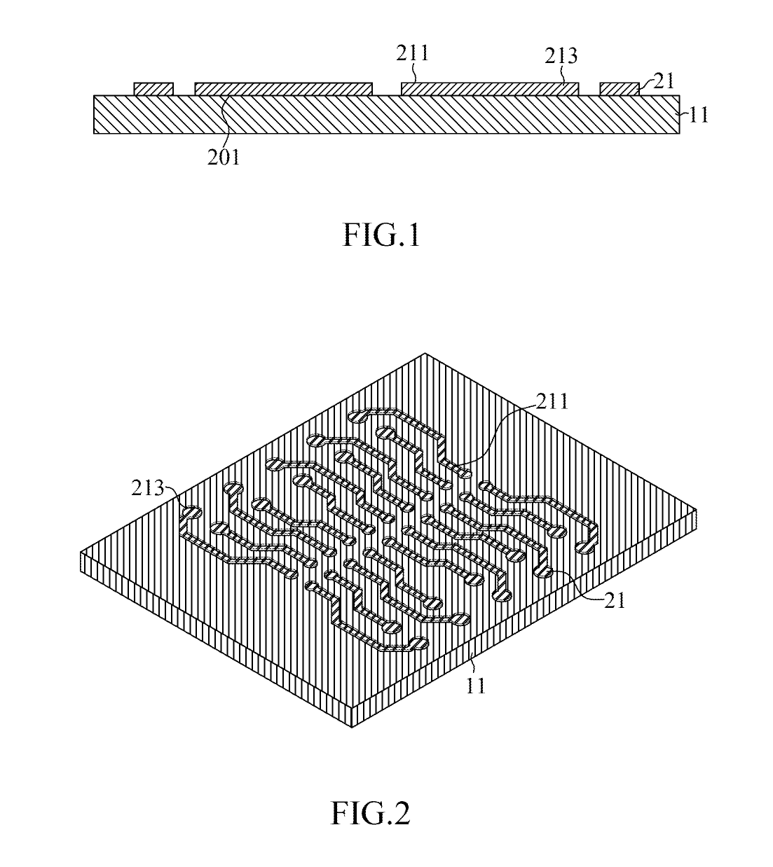

FIGS. 1-13 are schematic views showing a method of making an interconnect substrate that includes a first wiring layer, vertical connecting elements, a resin layer, a buffering layer and a stress modulator in accordance with the first embodiment of the present invention.

FIGS. 1 and 2 are cross-sectional and top perspective views, respectively, of the structure with a first wiring layer 21 formed on a sacrificial carrier 11 by metal deposition and metal patterning process. The sacrificial carrier 11 typically is made of copper, aluminum, iron, nickel, tin, stainless steel, silicon, or other metals or alloys, but any other conductive or non-conductive material also may be used. In this embodiment, the sacrificial carrier 11 is made of an iron-based material. The first wiring layer 21 is a patterned metal layer and has a first conductive surface 201 detachably attached to the sacrificial carrier 11. The first wiring layer 21 typically is made of copper and can be pattern deposited by numerous techniques, such as electroplating, electroless plating, evaporating, sputtering or their combinations, or be thin-film deposited followed by a metal patterning process. For a conductive sacrificial carrier 11, the first wiring layer 21 is deposited typically by plating of metal. The metal patterning techniques include wet etching, electro-chemical etching, laser-assist etching, and their combinations with an etch mask (not shown) thereon that defines the first wiring layer 21. In this illustration, the first wiring layer 21 includes interconnect pads 211 for device connection and routing traces 213 integrated with the interconnect pads 211.

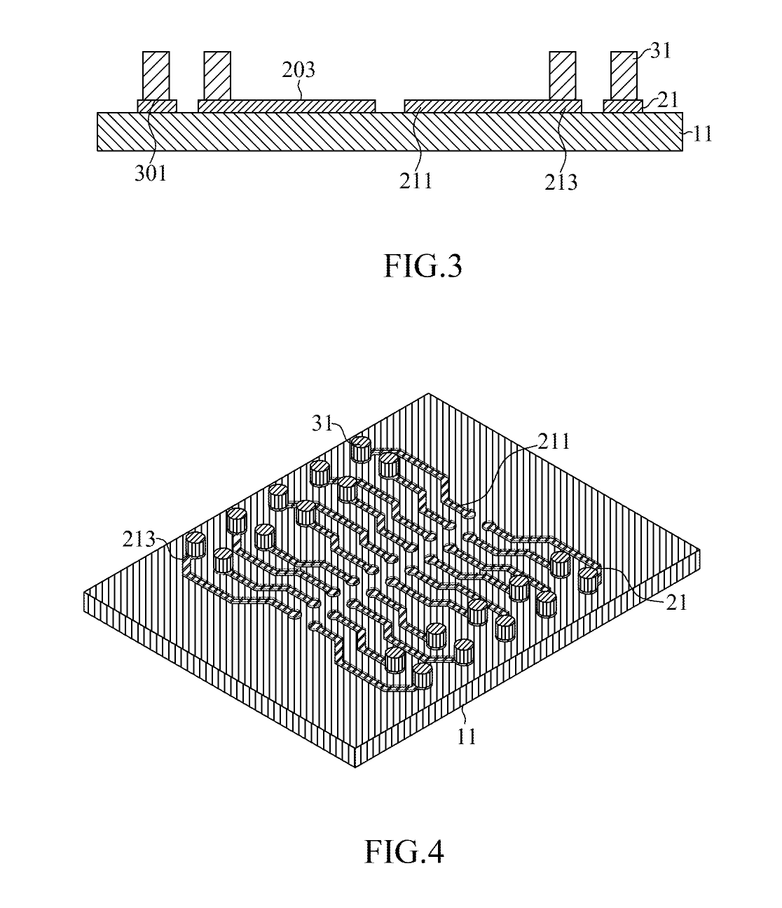

FIGS. 3 and 4 are cross-sectional and top perspective views, respectively, of the structure with vertical connecting elements 31 on a second conductive surface 203 of the first wiring layer 21. In this embodiment, the vertical connecting elements 31 are illustrated as metal pillars and each have a first end 301 electrically coupled to and in contact with the routing traces 213.

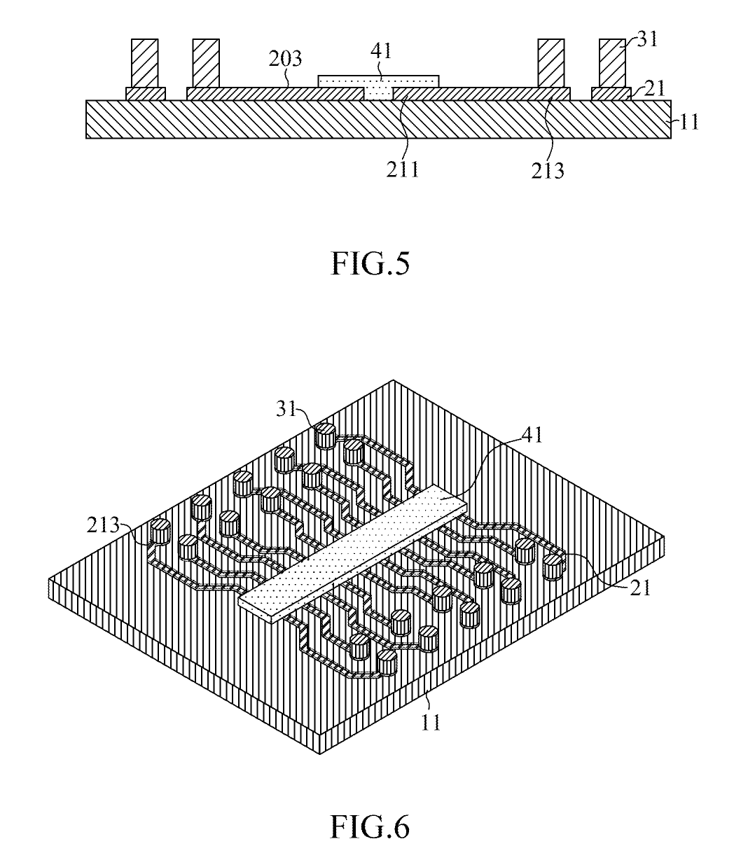

FIGS. 5 and 6 are cross-sectional and top perspective views, respectively, of the structure with a buffering layer 41 dispensed on the interconnect pads 211. The buffering layer 41 typically is an adhesive layer and covers the interconnect pads 211 from above and further extends into gaps between the interconnect pads 211.

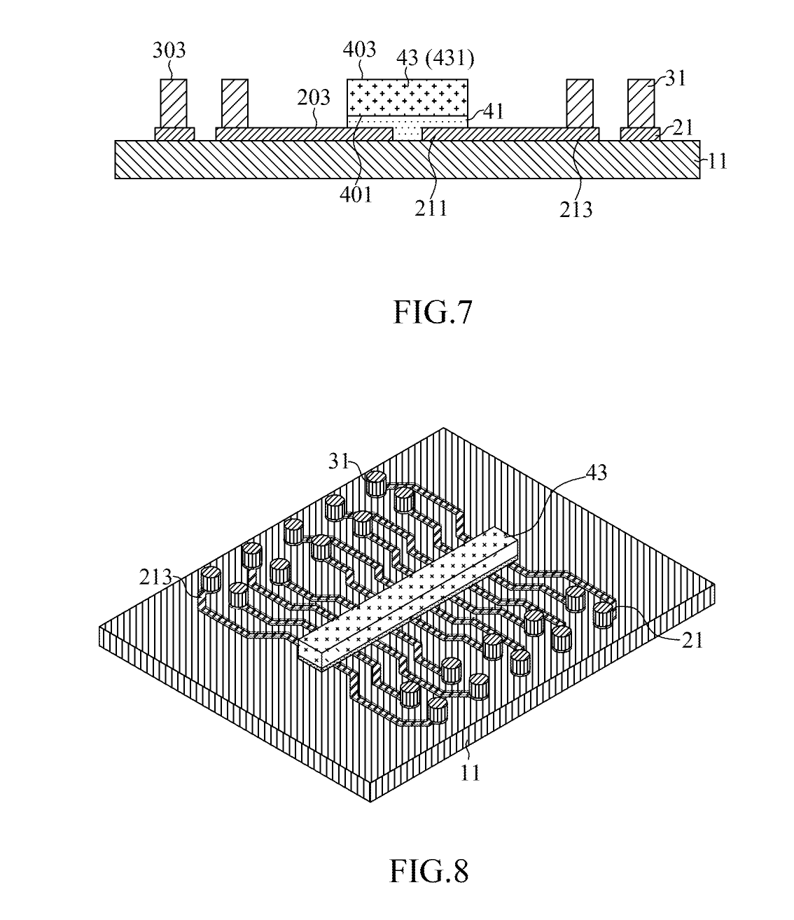

FIGS. 7 and 8 are cross-sectional and top perspective views, respectively, of the structure with a stress modulator 43 attached to the first wiring layer 21 by the buffering layer 41. The stress modulator 43 has a low coefficient of thermal expansion (<10 ppm/° C.) and thus has a better matched CTE with silicon chip than that of the resin laminates. The material suitable for the stress modulator 43 includes ceramic, silicon, glass, composite materials, metal alloys and others. In this embodiment, the stress modulator 43 is a ceramic slug 431, and has a first side 401 in contact with the buffering layer 41 and a second side 403 substantially coplanar with second ends 303 of the vertical connecting elements 31. As a result, the stress modulator 43 overlaps and is spaced from the interconnect pads 211 by the buffering layer 41 between the first side 401 of the stress modulator 43 and the second conductive surface 203 of the first wiring layer 21.

FIG. 9 is a cross-sectional view of the structure with a resin layer 51 on the sacrificial carrier 11, the first wiring layer 21, the vertical connecting elements 31 and the stress modulator 43 from above by, for example, resin-glass lamination, resin-glass coating or molding. The resin layer 51 surrounds and conformally coats and covers sidewalls of the vertical connecting elements 31 and the stress modulator 43, and extends into gaps between the routing traces 213. As a result, the resin layer 51 has a first dielectric surface 501 in contact with the sacrificial carrier 11 and substantially coplanar with the first conductive surface 201 of the first wiring layer 21.

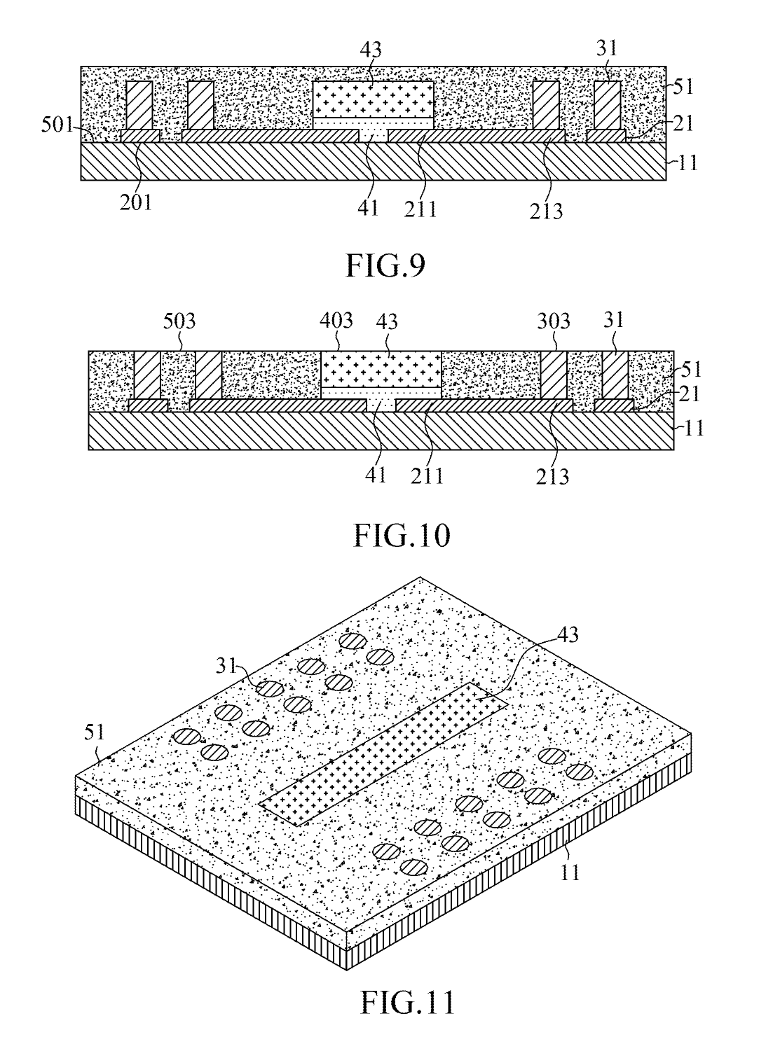

FIGS. 10 and 11 are cross-sectional and top perspective views, respectively, of the structure with the vertical connecting elements 31 and the stress modulator 43 exposed from above. The upper portion of the resin layer 51 can be removed by grinding. In this illustration, the resin layer 51 has a second dielectric surface 503 substantially coplanar with the second ends 303 of the vertical connecting elements 31 and the second side 403 of the stress modulator 43.

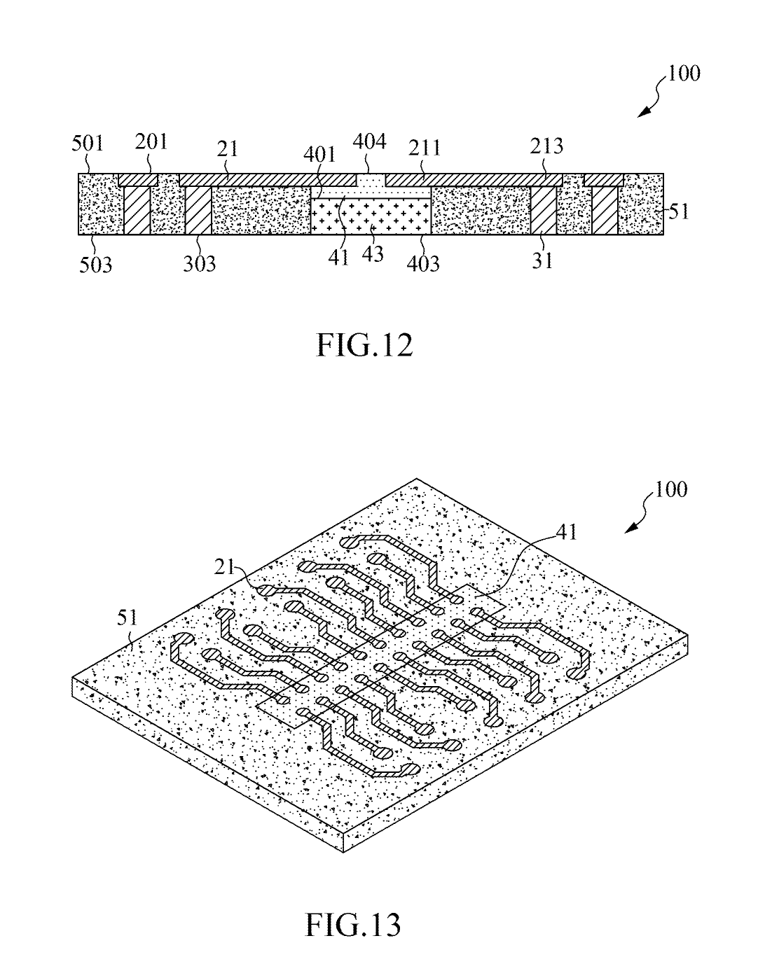

FIGS. 12 and 13 are cross-sectional and top perspective views, respectively, of the structure after removal of the sacrificial carrier 11 and being inverted. The sacrificial carrier 11 can be removed to expose the first conductive surface 201 of the first wiring layer 21 and the first dielectric layer 501 of the resin layer 51 as well as an external surface 404 of the buffering layer 41 by numerous techniques including wet chemical etching using acidic solution (e.g., ferric chloride, copper sulfate solutions), or alkaline solution (e.g., ammonia solution), electro-chemical etching, or mechanical process such as a drill or end mill followed by chemical etching. In this embodiment, the sacrificial carrier 11 made of an iron-based material is removed by a chemical etching solution that is selective between copper and iron so as to prevent the first wiring layer 21 made of copper from being etched during removal of the sacrificial carrier 11.

Accordingly, an interconnect substrate 100 is accomplished and includes the first wiring layer 21, the vertical connecting elements 31, the buffering layer 41, the stress modulator 43 and the resin layer 51.

The first wiring layer 21 is disposed adjacent to the first dielectric surface 501 of the resin layer 51, and includes the interconnect pads 211 disposed in the buffering layer 41 and superimposed over the first side 401 of the stress modulator 43 and the routing traces 213 disposed in the resin layer 51 and electrically connecting the interconnect pads 211 and the vertical connecting elements 31. In this embodiment, the first conductive surface 201 of the first wiring layer 21 is substantially coplanar with the first dielectric surface 501 of the resin layer 51 and the external surface 404 of the buffering layer 41, whereas the second ends 303 of the vertical connecting elements 31 are substantially coplanar with the second dielectric surface 503 of the resin layer 51 and the second side 403 of the stress modulator 43. As a result, the first conductive surface 201 of the first wiring layer 21 exposed from the first dielectric surface 501 of the resin layer 51 can provide top electrical contacts for device connection, and the second ends 303 of the vertical connecting elements 31 exposed from the second dielectric surface 503 of the resin layer 51 can provide bottom electrical contacts for next-level connection.

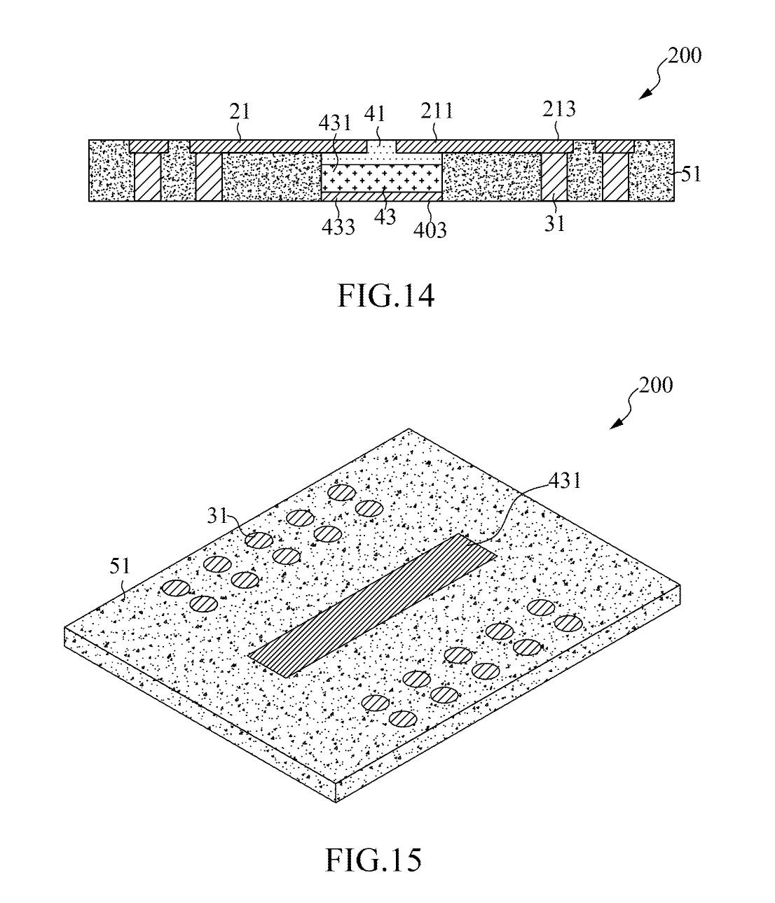

FIGS. 14 and 15 are cross-sectional and bottom perspective views, respectively, of another aspect of the interconnect substrate in accordance with the first embodiment. The interconnect substrate 200 is similar to those illustrated in FIG. 12, except that the stress modulator 43 has a metal layer 433 at the second side 403 thereof.

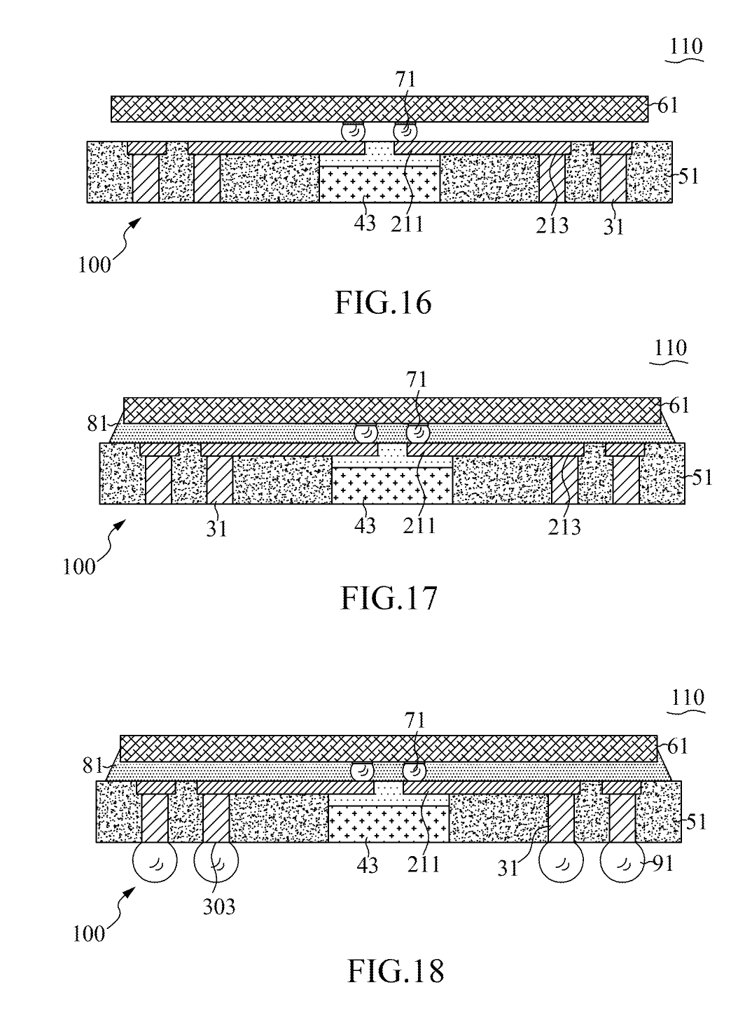

FIG. 16 is a cross-sectional view of a semiconductor assembly 110 with a semiconductor device 61 electrically connected to the interconnect substrate 100 illustrated in FIG. 12. The semiconductor device 61, illustrated as a chip, is face-down mounted on the interconnect pads 211 through bumps 71. As the low CTE of the stress modulator 43 can reduce CTE mismatch between the semiconductor device 61 and the bump attachment area covered by the stress modulator 43 from below and inhibit warpage in the bump attachment area during thermal cycling, the bumps 71 aligned with and completely covered by the stress modulator 43 from below will not suffer from cracking, thereby avoiding disconnection between the semiconductor device 61 and the interconnect substrate 100.

FIG. 17 is a cross-sectional view of the semiconductor assembly 110 of FIG. 16 further provided with an underfill 81. Optionally, the underfill 81 may be further provided to fill gaps between the semiconductor device 61 and the interconnect substrate 100.

FIG. 18 is a cross-sectional view of the semiconductor assembly 110 of FIG. 17 further provided with solder balls 91. Optionally, the solder balls 91 may be further mounted on the second ends 303 of the vertical connecting elements 31 for next-level connection.

### Embodiment 2

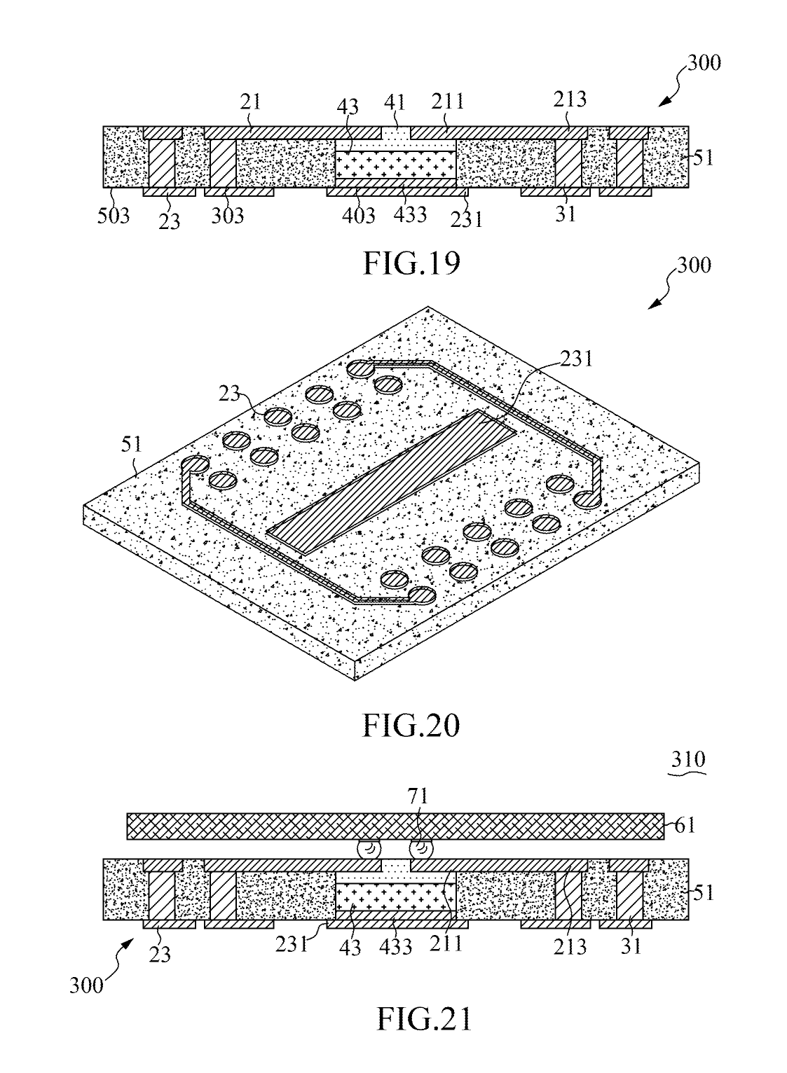

FIGS. 19 and 20 are cross-sectional and bottom perspective views, respectively, of another interconnect substrate in accordance with the second embodiment of the present invention.

For purposes of brevity, any description in Embodiment 1 is incorporated herein insofar as the same is applicable, and the same description need not be repeated.

The interconnect substrate 300 is similar to that illustrated in FIG. 14, except that it further includes a second wiring layer 23 that laterally extends on the second dielectric surface 503 of the resin layer 51 and the second side 403 of the stress modulator 43. The second wiring layer 23 is a patterned metal layer and typically made of copper. In this illustration, the second wiring layer 23 is electrically connected to the second ends 303 of the vertical connecting elements 31 and has a thermal paddle 231 in direct contact with the metal layer 433 of the stress modulator 43. As a result, the second wiring layer 23 can be electrically connected to the interconnect pads 211 through the vertical connecting elements 31 and the routing traces 213 and thermal conductible to the stress modulator 43. For better thermal dissipation, the buffering layer 41 preferably is a thermally conductive adhesive, and the thermal paddle 231 has a lateral dimension larger than that of the stress modulator 43 to establish a larger thermal dissipation surface area than the stress modulator 43.

FIG. 21 is a cross-sectional view of a semiconductor assembly 310 with a semiconductor device 61 electrically connected to the interconnect substrate 300 illustrated in FIG. 19. The semiconductor device 61 is face-down mounted on the interconnect pads 211 through bumps 71. In this embodiment, the heat generated by the semiconductor device 61 can be conducted away through the stress modulator 43 and the thermal paddle 231.

### Embodiment 3

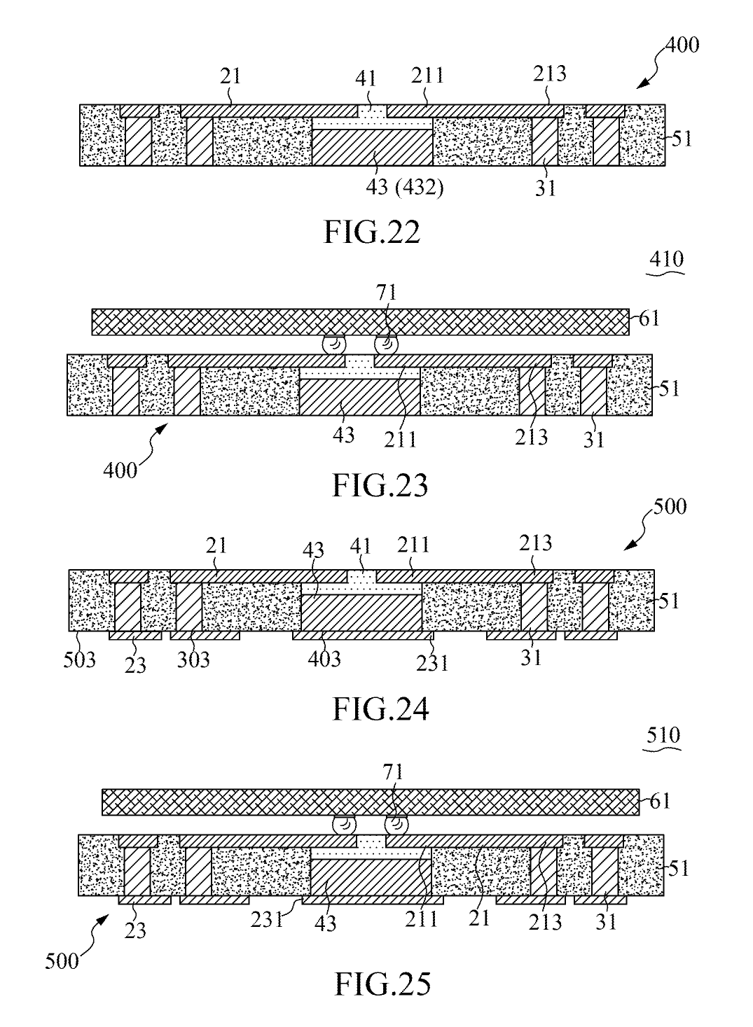

FIG. 22 is a cross-sectional view of yet another interconnect substrate in accordance with the third embodiment of the present invention.

For purposes of brevity, any description in the Embodiments above is incorporated herein insofar as the same is applicable, and the same description need not be repeated.

The interconnect substrate 400 is similar to that illustrated in FIG. 12, except that the stress modulator 43 is a metal slug 432 (typically made of copper) and the buffering layer 41 is an adhesive with low CTE (<10 ppm/° C.). Accordingly, even if the CTE of the stress modulator 43 is not less than 10 ppm/° C., the pad disposition area covered by the buffering layer 41 can have a better matched CTE for flip chip attachment owing to the low CTE of the buffering layer 41.

FIG. 23 is a cross-sectional view of a semiconductor assembly 410 with a semiconductor device 61 electrically connected to the interconnect substrate 400 illustrated in FIG. 22. The semiconductor device 61 is face-down mounted on the interconnect pads 211 through bumps 71. As the combination of the buffering layer 41 and the stress modulator 43 can reduce CTE mismatch between the semiconductor device 61 and the bump attachment area covered by the buffering layer 41 from below and inhibit warpage in the bump attachment area during thermal cycling, the bumps 71 aligned with and completely covered by the buffering layer 41 and the stress modulator 43 from below will not suffer from cracking, thereby avoiding disconnection between the semiconductor device 61 and the interconnect substrate 400.

### Embodiment 4

FIG. 24 is a cross-sectional view of yet another interconnect substrate in accordance with the fourth embodiment of the present invention.

For purposes of brevity, any description in the Embodiments above is incorporated herein insofar as the same is applicable, and the same description need not be repeated.

The interconnect substrate 500 is similar to that illustrated in FIG. 22, except that it further includes a second wiring layer 23 that laterally extends on the second dielectric surface 503 of the resin layer 51 and the second side 403 of the stress modulator 43 and is electrically connected to the second ends 303 of the vertical connecting elements 31. In this illustration, the second wiring layer 23 has a thermal paddle 231 in direct contact with the metallic second side 403 of the stress modulator 43. For better thermal dissipation, the buffering layer 41 preferably is a thermally conductive adhesive with low CTE (<10 ppm/° C.).

FIG. 25 is a cross-sectional view of a semiconductor assembly 510 with a semiconductor device 61 electrically connected to the interconnect substrate 500 illustrated in FIG. 24. The semiconductor device 61 is flip-chip mounted on the first wiring layer 21 through bumps 71 in contact with the interconnect pads 211.

As illustrated in the aforementioned embodiments, a distinctive interconnect substrate is configured to have interconnect pads superimposed over a stress modulator and exhibit improved reliability, which includes a first wiring layer, vertical connecting elements, a resin layer, a buffering layer, a stress modulator and optionally a second wiring layer.

The stress modulator is a non-electronic component without signal routing electrically connected thereto and may be made of inorganic material. In a preferred embodiment, the stress modulator has a coefficient of thermal expansion less than 10 ppm/° C. As the low CTE of the stress modulator can reduce CTE mismatch between the chip and the pad disposition area covered by the stress modulator and inhibit warpage in the pad disposition area during thermal cycling, cracking of conductive joints (such as bumps) aligned with and completely covered by the stress modulator can be avoided.

The vertical connecting elements laterally surround the stress modulator and can serve as vertical signal transduction pathways or provide ground/power plane for power delivery and return. In a preferred embodiment, the vertical connecting elements are metal posts, and each have the first end in contact with and electrical connection with the second conductive surface of the first wiring layer and the second end substantially coplanar with the second side of the stress modulator and the second dielectric surface of the resin layer.

The resin layer can provide mechanical bonds between the stress modulator and the vertical connecting elements and cover sidewalls of the stress modulator and sidewalls of the vertical connecting elements as well as lateral surfaces of the routing traces in contact with the first ends of the vertical connecting elements. In a preferred embodiment, the resin layer mainly includes an organic resin binder and particulate inorganic fillers. As the particulate inorganic fillers can have a coefficient of thermal expansion less than 10 ppm/° C., the CTE of the resin layer can be adjusted to be more compatible to that of the vertical connecting elements and the stress modulator.

The first wiring layer is a patterned metal layer and provides the interconnect pads located over the first side of the stress modulator and the routing traces that extend laterally from the interconnect pads to peripheral area for electrical connection with the vertical connecting elements. As the interconnect pads for device connection are superimposed over the first side of the stress modulator, I/O disconnection between the interconnect pads and a semiconductor device flip-chip mounted on the interconnect pads can be avoided.

The buffering layer preferably is an adhesive layer for the attachment of the stress modulator to the second conductive surface of the interconnect pads before provision of the resin layer. The buffering layer is laterally surrounded by the resin layer and covers the first side of the stress modulator as well as lateral surfaces of the interconnect pads. As a result, the first side of the stress modulator is spaced from the interconnect pads by the buffering layer without electrical joints in contact with the first side of the stress modulator. In a preferred embodiment, the buffering layer has an external surface exposed from the first dielectric surface of the resin layer and substantially coplanar with the first conductive surface of the first wiring layer and the first dielectric surface of the resin layer. The buffering layer can have a shape with the same or similar topography as the first side of the stress modulator. For certain applications, the buffering layer itself can have a low CTE (<10 ppm/° C.) so that a matched CTE for flip chip assembly can be established regardless of the CTE of the stress modulator. For better thermal dissipation, the buffering layer may be a thermally conductive adhesive so that the heat generated by the chip on the interconnect pads can be transferred to the stress modulator and further spread out.

The second wiring layer is a patterned metal layer electrically connected to the second ends of the vertical connecting elements and laterally extending on the second dielectric surface of the resin layer. Accordingly, the second wiring layer can be electrically connected to the interconnect pads through the vertical connecting elements and the routing traces and provides electrical contacts for next-level connection. Further, the second wiring layer may have a thermal paddle in contact with the second side of the stress modulator. Preferably, the stress modulator has a metal layer at its second side in combined with the thermal paddle.

The present invention also provides a semiconductor assembly in which a semiconductor device such as chip is electrically connected to the interconnect pads of the aforementioned interconnect substrate through a plurality of bumps aligned with and covered by the stress modulator. Preferably, each of the bumps for device connection is entirely positioned within the area completely covered by the stress modulator and does not laterally extend beyond peripheral edges of the stress modulator.

The term “cover” refers to incomplete or complete coverage in a vertical and/or lateral direction. For instance, in a preferred embodiment, the stress modulator completely covers the bumps regardless of whether other elements such as the first wiring layer and the buffering layer is between the stress modulator and the bumps.

The phrases “mounted on” and “attached to” include contact and non-contact with a single or multiple support element(s). For instance, in a preferred embodiment, the semiconductor device is mounted on the interconnect pads regardless of whether the semiconductor device is separated from the interconnect pads by the bumps.

The phrase “aligned with” refers to relative position between elements regardless of whether elements are spaced from or adjacent to one another or one element is inserted into and extends into the other element. For instance, in a preferred embodiment, the bumps are aligned with the stress modulator since an imaginary vertical line intersects the bumps and the stress modulator, regardless of whether another element is between the bumps and the stress modulator and is intersected by the line, and regardless of whether another imaginary vertical line intersects the stress modulator but not the bumps or intersects the bumps but not the stress modulator.

The phrases “electrically connected” and “electrically coupled” refer to direct and indirect electrical connection. For instance, in a preferred embodiment, the vertical connecting elements are electrically connected to the interconnect pads by the routing traces but are spaced from and do not contact the interconnect pads.

The interconnect substrate made by this method is reliable, inexpensive and well-suited for high volume manufacture. The manufacturing process is highly versatile and permits a wide variety of mature electrical and mechanical connection technologies to be used in a unique and improved manner. The manufacturing process can also be performed without expensive tooling. As a result, the manufacturing process significantly enhances throughput, yield, performance and cost effectiveness compared to conventional techniques.

The embodiments described herein are exemplary and may simplify or omit elements or steps well-known to those skilled in the art to prevent obscuring the present invention. Likewise, the drawings may omit duplicative or unnecessary elements and reference labels to improve clarity.

What is claimed is:

1. An interconnect substrate, comprising:
a resin layer having a first dielectric surface and an opposite second dielectric surface;
a first wiring layer disposed adjacent to the first dielectric surface and having a first conductive surface exposed from the first dielectric surface and an opposite second conductive surface at a level between the first dielectric surface and the second dielectric surface;
a plurality of vertical connecting elements disposed in the resin layer and each having a first end electrically connected to the second conductive surface and an opposite second end exposed from the second dielectric surface; and
a stress modulator disposed in the resin layer and having a first side facing in the second conductive surface and located at a level between the second conductive surface and the second dielectric surface, wherein the stress modulator is spaced from the first wiring layer by a buffering layer;
wherein the first wiring layer includes interconnect pads and routing traces integrated with the interconnect pads;
wherein the interconnect pads are disposed in the buffering layer and superimposed over the first side of the stress modulator;
wherein the routing traces are disposed in the resin layer and electrically connects the interconnect pads and the vertical connecting elements; and
wherein the buffering layer extends into gaps between the interconnect pads and the resin layer extends into gaps between the routing traces.

2. The interconnect substrate of claim 1, wherein the stress modulator has a coefficient of thermal expansion less than 10 ppm/° C.

3. The interconnect substrate of claim 1, wherein the stress modulator is a metal slug and the buffering layer has a coefficient of thermal expansion less than 10 ppm/° C.

4. The interconnect substrate of claim 1, wherein the buffering layer has an external surface substantially coplanar with the first dielectric surface of the resin layer.

5. The interconnect substrate of claim 1, wherein the stress modulator has a metal layer at a second side thereof opposite to the first side.

6. The interconnect substrate of claim 1, wherein the second ends of the vertical connecting elements are substantially coplanar with the second dielectric surface of the resin layer.

7. The interconnect substrate of claim 1, further comprising a second wiring layer disposed on the second dielectric surface of the resin layer and electrically connected to the second ends of the vertical connecting elements.

8. A flip chip assembly, comprising:
the interconnect substrate of claim 1; and
a semiconductor device disposed over the interconnect substrate and electrically coupled to the interconnect pads through a plurality of bumps, wherein the bumps of the semiconductor device are aligned with and covered by the stress modulator.
